(19) United States
(12) Patent Application Publication
(10) Pub. No.: US 2006/0089008 A1
(43) Pub. Date: Apr. 27, 2006

(54) Methods of manufacturing silicon oxide isolation layers and semiconductor devices that include such isolation layers

(76) Inventors: Eunkee Hong, Gyeonggi-do (KR); Ju-Seon Goo, Gyeonggi-do (KR); Kyu-Tae Na, Seoul (KR); Sang-Ho Rha, Seoul (KR)

Correspondence Address: MYERS BIGEL SIBLEY & SAJOVEC, PO BOX 37428, RALEIGH, NC, 27627, US

(21) Appl. No.: 11/259,408

(22) Filed: Oct. 26, 2005

(30) Foreign Application Priority Data
Oct. 27, 2004 (KR) 10-2004-0086016

(51) Int. Cl. H01L 21/31; H01L 21/469

(52) U.S. Cl. 438/778

(57) ABSTRACT

Methods of manufacturing silicon oxide layers for semiconductor devices are provided in which a substrate having a recess is coated with a spin-on-glass film so that the recess is filled with the spin-on-glass film. A main thermal treatment is performed on the spin-on-glass film at about 600 to about 1,000° C. at about 1 ATM to about 50 ATM so that the spin-on-glass film is converted into a relatively dense silicon oxide layer.

### CROSS REFERENCE TO RELATED APPLICATION

This application claims priority under 35 U.S.C. § 119 to Korean Patent Application No. 2004-86016, filed on Oct. 27, 2004, the disclosure of which is herein incorporated by reference in its entirety.

### FIELD OF THE INVENTION

The present invention relates to semiconductor devices and, more particularly, to methods of manufacturing isolation layers for semiconductor devices and related methods of manufacturing semiconductor devices that include such isolation layers.

### BACKGROUND OF THE INVENTION

As semiconductor devices become more highly integrated, the aspect ratio of recesses in the semiconductor device that are defined by various patterns tend to become larger. Thus, considerable resources have been expended to identify films that are capable of uniformly filling up such recesses without leaving voids in the semiconductor device. One film that is widely used to fill recesses in semiconductor devices is a high density plasma oxide layer. However, when the aspect ratio of the recess exceeds, for example, about 3.0, the high density plasma oxide layer may not efficiently fill up the recess, and a void may be generated.

It is also known to use a boron phosphorus silicate glass (BPSG) layer to fill recesses in a semiconductor device. However, BPSG layers are typically formed by a reflow process at a temperature over about 700° C. Such a process may apply a thermal shock to the semiconductor device. In addition, since the BPSG layer has a relatively large etch rate, the BPSG layer may tend to be too easily removed by a subsequent etch process. As a result, BPSG layers are typically not used to fill recesses in semiconductor devices that have very small design rules.

Recesses between patterns may also be filled using a silicon oxide layer. Korean Patent Laid-open Publication No. 2002-41582 discloses a method of filling a recess using a silicon oxide layer. In this method, the recess is filled with an undoped silicate glass (USG) film, a high density plasma oxide layer or a SOG layer. The USG film, the high density plasma oxide layer and the SOG layer are thermally treated at a pressure of about 1.5 ATM to about 50 ATM.

### SUMMARY

Pursuant to embodiments of the present invention, methods of manufacturing semiconductor devices are provided in which a spin-on-glass solution is provided in a recess on a substrate. A spin-on-glass film such as, for example, polysilazane is then formed on the substrate and in the recess. The recess may have an aspect ratio, for example, that exceeds 3.0. A silicon oxide layer is formed in the recess by performing a main thermal treatment on the spin-on-glass film in the recess at a temperature of about 600° C. to about 1,000° C. and at a pressure of about 1 ATM to about 50 ATM.

In certain embodiments of the present invention, the recess may be a trench formed in an upper portion of the substrate. In other embodiments, the semiconductor device may include a first gate pattern and a second gate pattern on the substrate with a space therebetween, and the recess may be the space between the gate patterns. The main thermal treatment may be performed, for example, for about 20 minutes to about 60 minutes and/or may be performed in an oxidation atmosphere. Such an oxidation atmosphere may be obtained, for example, by using at least one gas selected from the group consisting of a water vapor and an oxygen gas.

A preliminary thermal treatment may optionally be performed on the spin-on-glass film at a temperature of, for example, about 100° C. to about 300° C. and at a pressure of, for example, about 1 ATM to about 50 ATM.

The methods may also include forming a pad oxide layer pattern and a pad nitride layer pattern on the substrate prior to providing the spin-on-glass solution in the recess, and planarizing the silicon oxide layer to expose the pad nitride layer pattern after the main thermal treatment is performed. A liner may also be formed on an inner face of the recess, where the liner comprises, for example, silicon nitride.

Methods of manufacturing silicon oxide isolation layers of a semiconductor device are also provided.

### BRIEF DESCRIPTION OF THE DRAWINGS

The above and other advantages of the present invention will become readily apparent by reference to the following detailed description when considered in conjunction with the accompanying drawings in which:

FIG. 1 is a cross-sectional diagram illustrating semiconductor devices in accordance with example embodiments of the present invention;

FIGS. 2A to 2E are cross-sectional diagrams illustrating methods of manufacturing isolation layers or regions in the semiconductor devices of FIG. 1 in accordance with example embodiments of the present invention; and

FIGS. 3A to 3D are cross-sectional diagrams illustrating methods of manufacturing insulation interlayer patterns and contact plugs in semiconductor devices in accordance with example embodiments of the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like may be used herein for ease of description to describe one element or feature's relationship to another element(s) or feature(s) as, for example, illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

In the present disclosure, references are made to recesses and/or trenches that are “on” a substrate. It will be understood that these references encompass both a recess (or a trench) that is physically above the substrate such as, for example, the open area between two gate patterns that are formed on top of a substrate as well as recesses (or a trench) that is formed in, or hollowed out of, the top surface of the substrate such as, for example, the recess/trench that is formed in a semiconductor substrate as part of conventional trench isolation processes.

Various embodiments of the present invention will now be described with reference to the accompanying drawings.

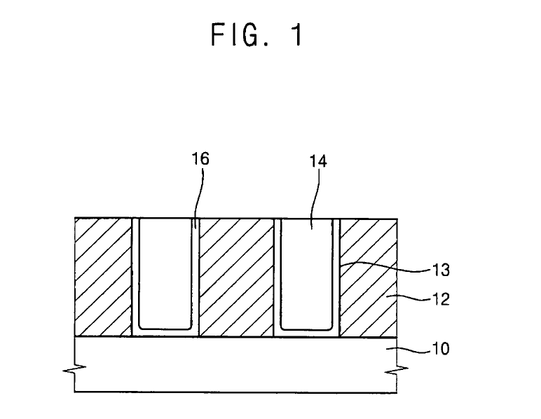

FIG. 1 is a cross-sectional diagram illustrating semiconductor devices in accordance with example embodiments of the present invention.

Referring to FIG. 1, a pattern 12 having a recess 13 that has a relatively large aspect ratio is formed on a substrate such as, for example, a semiconductor substrate 10. The recess 13 may, for example, be a trench. The pattern 12 may, for example, be a gate pattern or an insulation interlayer pattern.

A liner 16 may uniformly cover an inner face of the recess 13. The liner 16 may include, for example, silicon nitride. In certain embodiments of the present invention, the liner 16 may have a relatively uniform thickness and/or may be continuously formed.

A silicon oxide layer pattern 14 is formed on the liner 16. The silicon oxide layer pattern 14 may be formed, for example, by depositing a spin-on-glass (SOG) solution in the recess to form an SOG film (not shown). A main thermal treatment may be performed on the SOG film at a temperature of, for example, about 600° C. to about 1,000° C. and at a pressure of, for example, about 1 ATM to about 50 ATM. The main thermal treatment may be performed in an oxidation atmosphere. The oxidation atmosphere may be produced, for example, using a water vapor (H₂O) and/or an oxygen (O₂) gas. The main thermal treatment may be performed, for example, for about 20 minutes to about 60 minutes.

In addition to the main thermal treatment, in certain embodiments of the present invention, a preliminary thermal treatment may be performed on the SOG film at a temperature of, for example, about 100° C. to about 300° C. The preliminary thermal treatment may harden the SOG film. In such embodiments, the SOG film may then be partially planarized to form the silicon oxide layer pattern 14.

The silicon oxide layer pattern 14 according to an example embodiment of the present invention may be relatively free of voids such that the recess 13 may be fully filled with the oxide layer pattern 14. Thus, failures due to voids may be reduced or prevented in subsequent processing steps.

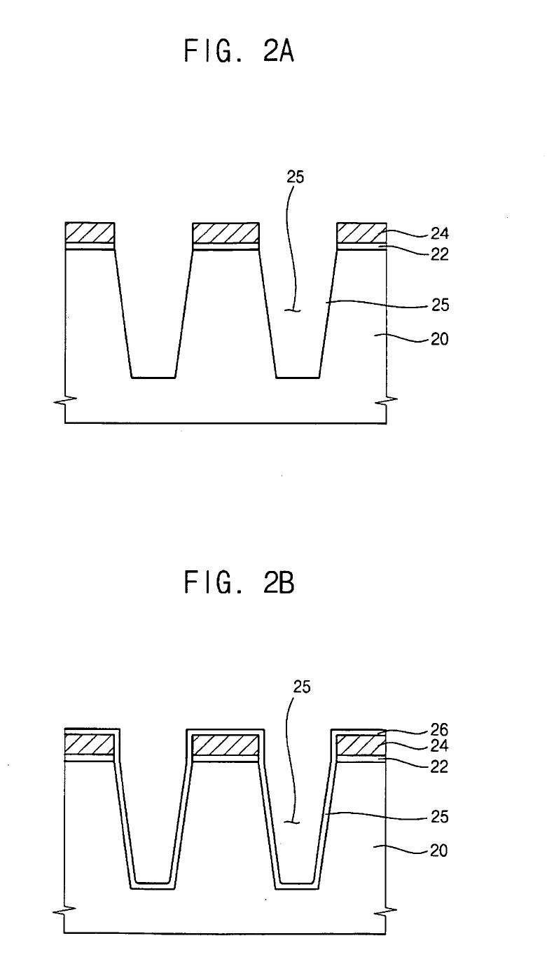

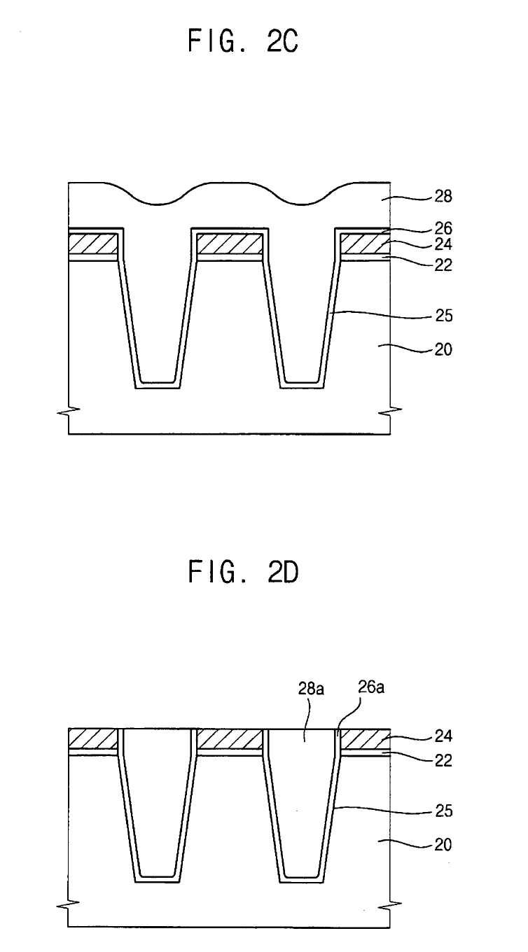

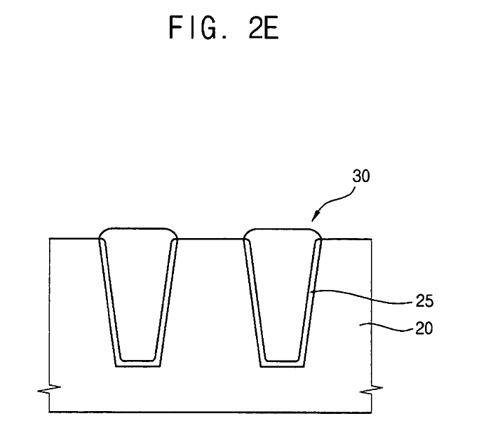

FIGS. 2A to 2E are cross-sectional diagrams illustrating methods of manufacturing isolation layers or regions in a semiconductor device in accordance with example embodiments of the present invention.

Referring to FIG. 2A, a pad oxide layer (not shown) and a pad nitride layer (not shown) are formed on a substrate 20. The pad oxide layer and the pad nitride layer are patterned to form a pad oxide layer pattern 22 and a pad nitride layer pattern 24, respectively. A portion of the substrate 20 such as, for example, the portion exposed through the pad oxide layer pattern 22 and the pad nitride layer pattern 24, is etched to form a trench 25. Because the substrate 20 may have an etch rate that is substantially larger than the etch rate of the pad nitride layer pattern 24, the trench may be efficiently formed by an etching process.

In certain embodiments of the present invention, a curing process may be performed on an inner face portion of the trench 25 to cure damage to the inner face portion of the trench 25 that may occur, for example, during the etching process. When such a curing process is performed, an oxide layer (not shown) may form on the inner surface of the trench 25.

As shown in FIG. 2B, a liner 26 is formed. The liner 26 may cover the trench 25, the pad oxide layer pattern 22 and the pad nitride layer pattern 24. In certain embodiments of the present invention, the liner 26 may have a relatively uniform thickness, and may be continuously formed. The liner 26 may reduce or prevent a leakage current from an isolation layer that is formed in the trench 25 in a later processing step. The liner 26 may also prevent the inner surface of the trench 25 from oxidizing.

As disclosed in Korean Patent Laid-Open Publication No. 2002-41582, a liner may include aluminum oxide. When the liner includes aluminum oxide, the liner may be oxidized in a subsequent thermal treatment such as, for example, a preliminary thermal treatment and a main thermal treatment. In order to reduce the possibility of such oxidation, in certain embodiments of the present invention, the liner 26 may include silicon nitride instead of aluminum oxide.

In accordance with an example embodiment of the present invention, an oxide layer (not shown) may be formed on the liner 26.

Referring to FIG. 2C, the substrate 20 having the trench 25 is provided with an SOG (spin on glass) solution so that an SOG film is formed on the substrate 20 and in the trench 25. The SOG film may be formed, for example, by using a spin coating method. The SOG solution used for forming the SOG film may include polysilazane in certain embodiments of the present invention.

A preliminary-thermal treatment may then be performed on the SOG film. When the temperature of the preliminary thermal treatment is below about 100° C., a solvent that is included in typical SOG solutions may be insufficiently volatilized. When the temperature of the preliminary thermal treatment is above about 300° C., it is possible that the efficiency of the subsequent main thermal treatment may decrease. Thus, in specific embodiments of the present invention, the preliminary thermal treatment is performed at about 100° C. to about 300° C. In one specific embodiment, the preliminary thermal treatment is performed at a temperature of about 150° C. to about 250° C.

When the preliminary thermal treatment is performed at a pressure below about 1 ATM, certain SOG films may not efficiently cure. When the preliminary thermal treatment is performed at a pressure above about 50 ATM, the preliminary thermal treatment may be unstable in certain situations. Thus, in certain embodiments of the present invention, the preliminary thermal treatment may be performed at a pressure of about 1 ATM to about 50 ATM. In certain embodiments, the preliminary thermal treatment may be performed at a pressure of about 10 ATM to about 40 ATM. In more specific embodiments, the preliminary thermal treatment may be performed at a pressure of about 20 ATM to about 30 ATM.

The preliminary thermal treatment may be performed in an oxidation atmosphere, which may provide for better adhesion between the SOG film and the substrate 20. The oxidation atmosphere may be obtained, for example, using a water vapor (H₂O) and/or an oxygen (O₂) gas.

Thus, in certain embodiments of the present invention, the preliminary thermal treatment may be preformed at a temperature of about 100° C. to about 300° C. and at a pressure of about 1 ATM to about 50 ATM in an oxidation atmosphere. In such embodiments, the solvent included in the SOG solution may be efficiently volatilized in the preliminary thermal treatment. The preliminary thermal treatment is an optional process, and thus may be omitted in certain embodiments of the present invention.

The main thermal treatment is performed on the SOG film to harden the SOG film. Thus, the SOG film may become a silicon oxide layer 28. When the main thermal treatment is performed at a temperature above about 600° C., typically the silicon oxide layer 28 may be well cured. When the main thermal treatment is performed at a temperature above about 1,000° C., a thermal stress may be applied to the substrate 20, and/or the liner 26 including the silicon nitride may be oxidized. Thus, in certain embodiments of the present invention, the main thermal treatment may be performed at a temperature of about 600° C. to about 1,000° C. In more specific embodiments, the main thermal treatment may be performed at a temperature of about 600° C. to about 850° C. In still more specific embodiments, the main thermal treatment may be performed at a temperature of about 650° C. to about 800° C.

The main thermal treatment may be performed at a pressure of, for example, about 1 ATM to about 50 ATM in an oxidation atmosphere. Under certain conditions, the silicon oxide layer 28 may harden within, for example, about 20 minutes. If the main thermal treatment extends for longer than, for example, about 60 minutes, a thermal stress may, in certain situations, be applied to the substrate 40. Thus, in certain embodiments of the present invention, the main thermal treatment may be performed for about 20 minutes to about 60 minutes.

Thus, in certain embodiments of the present invention, the main thermal treatment may be performed at a temperature of about 600° C. to about 1000° C. at a pressure of about 1 ATM to about 50 ATM in an oxidation atmosphere. The main thermal treatment may convert the SOG film into a silicon oxide layer 28. Because the SOG film is relatively fluid, the silicon oxide layer 28 may be dense, and may have few if any voids such that the trench 25 is filled.

As shown in FIG. 2D, the silicon oxide layer 28 and the liner 26 may be planarized by a planarization process to expose the pad nitride layer pattern 24. Thus, a silicon oxide layer pattern 28a and a liner pattern 26a may be formed. As a result, a preliminary isolation layer including the silicon oxide layer pattern 28a and the liner pattern 26a is formed in the trench 25. The planarization process may, for example, be a chemical mechanical polish process or an etch-back process. These may be used alone or in a combination thereof.

As shown in FIG. 2E, the pad nitride layer pattern 24 and the pad oxide layer pattern 22 may be removed by, for example, a wet etching process that uses phosphoric acid. When the pad nitride layer pattern 24 and the pad oxide layer pattern 22 are removed, the preliminary isolation layer may be partially removed. Thus, the preliminary isolation layer may become an isolation layer 30 that fills the trench 25. The isolation layer 30 may be relatively free of voids.

If the silicon oxide layer 28 (see FIG. 2C) includes voids, such voids may result in one or more recesses when the silicon oxide layer 28 and the liner 26 are planarized and/or when the pad nitride layer pattern 24 and the pad oxide layer pattern 22 are removed. By forming the silicon oxide layer 28 using an SOG film that is relatively fluid, the formation of such recesses may be reduced and/or prevented. According to the example embodiments of the present invention, the silicon oxide layer 28, and hence the isolation layer 30, may be dense and relatively free of voids.

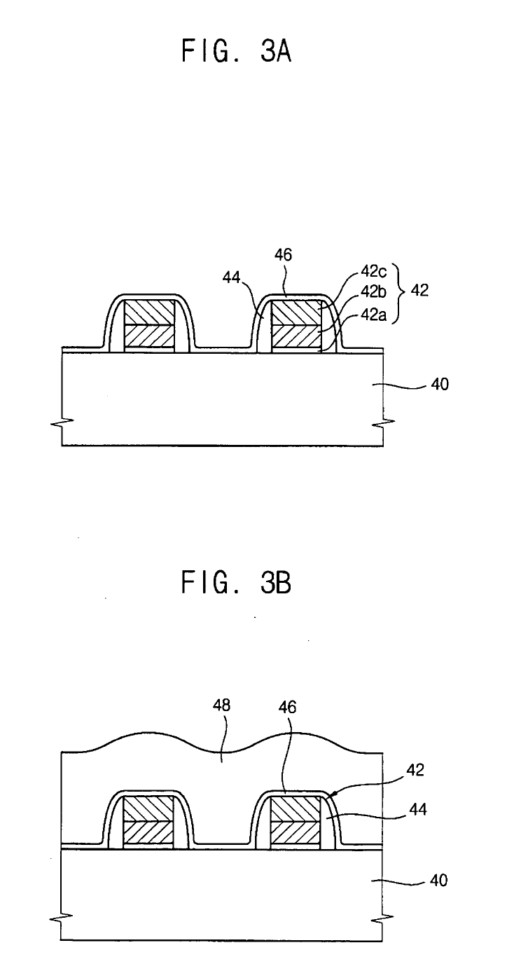

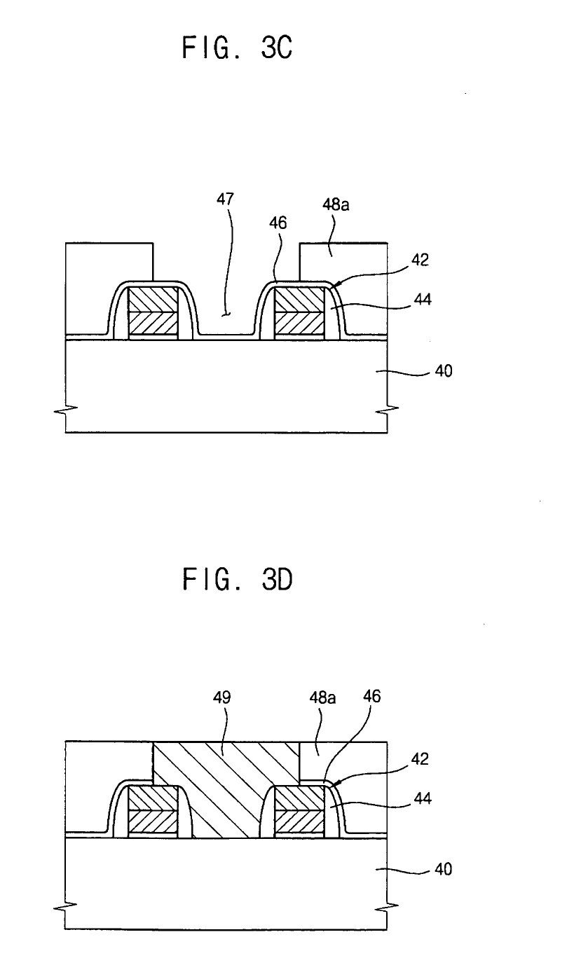

FIGS. 3A to 3D are cross-sectional diagrams illustrating methods of manufacturing an insulation interlayer pattern and a contact plug in semiconductor devices in accordance with example embodiments of the present invention.

A gate oxide layer, a gate conductive layer and a hard mask layer are sequentially formed on a substrate 40. As shown in FIG. 3A, the gate oxide layer, the gate conductive layer and the hard mask layer are then patterned to form a gate pattern 42 that includes a gate oxide layer pattern 42a, a gate conductive layer pattern 42b and a hard mask layer pattern 42c. The gate conductive layer pattern 42b may comprise, for example, a doped polysilicon, a metal and/or a metal silicide. The hard mask layer pattern 42c may comprise, for example, silicon nitride.

A gate spacer 44 is formed on a sidewall of the gate pattern 42. The gate spacer 44 may be formed, for example, by forming a silicon nitride film on the substrate 40 and on the gate pattern 42. The silicon nitride film may then be etched to form the gate spacer 44.

In certain embodiments of the present invention, impurities may be lightly doped into the exposed portion of the substrate 40 between the gate patterns 42 to form a shallow junction region, using the gate patterns 42 as an ion implantation mask. In other embodiments, impurities may be heavily doped into the portion of the substrate 40 exposed between the gate patterns 42 to form a deep junction region, using the gate patterns 42 as an ion implantation mask.

As is also shown in FIG. 3A, a liner 46 is formed on the substrate 40, the gate spacer 44 and the gate pattern 42. The liner 46 may be continuously formed, and may have a substantially uniform thickness. The liner 46 may include silicon nitride. It will be understood that the liner 46 is optional. Thus, the liner 46 may be omitted in certain embodiments of the present invention.

As shown in FIG. 3B, an SOG (spin on glass) solution is provided on the liner 46 to form an SOG film that covers the liner 46. The SOG film may be formed by using a spin coating method. The SOG solution used for forming the SOG film may include polysilazane.

A preliminary-thermal treatment may then be performed on the SOG film. As discussed above with respect to FIG. 2C, in certain embodiments of the present invention, the preliminary thermal treatment may be performed, for example, in an oxidation atmosphere at a temperature in the range of about 100° C. to about 300° C. and at a pressure of about 1 ATM to about 50 ATM. Such a preliminary thermal treatment may efficiently volatize the solvent included in the SOG solution. As discussed above, it will be appreciated that the preliminary thermal treatment is an optional process and may be omitted.

Next a main thermal treatment is performed on the SOG film which may harden the SOG film into the silicon oxide layer 48. As discussed above with respect to FIG. 2C, the main thermal treatment may be performed, for example, at a temperature of about 600° C. to about 1,000° C., at a pressure about 1 ATM to about 50 ATM, and in an oxidation atmosphere for about 20 minutes to about 60 minutes. This main thermal treatment may convert the SOG film into the silicon oxide layer 48. As the SOG film is relatively fluid, the silicon oxide layer 48 may be dense and relatively free of voids, and may fully cover the liner 46

As shown in FIG. 3C, the insulation layer 48 may then be patterned by a patterning process to form an insulation layer pattern 48a having a contact hole 47 that exposes a portion of the liner 46 between the gate patterns 42. The patterning process may, for example, be a wet etching process. Since the insulation layer 48 may be relatively free of voids, the electrical reliability of the insulation layer pattern 48a may be high even when a wet etching process is used.

As shown in FIG. 3D, a portion of the liner 46 is removed so that a liner pattern 46a is formed that exposes a portion of the substrate 40 between the gate patterns 42.

A conductive film (not shown) is formed on the insulation layer pattern 48a and in the contact hole 47. The conductive film may include a conductive material. The conductive film may then be planarized by a planarization process to expose the insulation layer pattern 48a so that a contact plug 49 is formed in the contact hole 47. The planarization process may, for example, be a CMP process and/or an etch-back process. The insulation layer 48, and hence the contact plug 49, may be dense and relatively free of voids.

According to example embodiments of the present invention, a recess having a relatively large aspect ratio may be efficiently filled with a dense film that is relatively free of voids. As a result, the electric reliability of the semiconductor device may be improved.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of manufacturing a semiconductor device, the method comprising:
providing a spin-on-glass solution in a recess on a substrate;
forming a spin-on-glass film on the substrate and in the recess; and
forming a silicon oxide layer in the recess by performing a main thermal treatment on the spin-on-glass film in the recess at a temperature of about 600° C. to about 1,000° C. and at a pressure of about 1 ATM to about 50 ATM.

2. The method of claim 1, the method further comprising performing a preliminary thermal treatment on the spin-on-glass film at a temperature of about 100° C. to about 300° C.

3. The method of claim 2, wherein the preliminary thermal treatment is performed at a pressure of about 1 ATM to about 50 ATM in an oxidation atmosphere.

4. The method of claim 1, wherein the spin-on-glass solution comprises polysilazane.

5. The method of claim 1, wherein the main thermal treatment is performed for about 20 minutes to about 60 minutes.

6. The method of claim 5, wherein the main thermal treatment is performed in an oxidation atmosphere.

7. The method of claim 6, wherein the oxidation atmosphere is obtained by using at least one gas selected from the group consisting of a water vapor and an oxygen gas.

8. The method of claim 1, wherein the recess is a trench formed in an upper portion of the substrate.

9. The method of claim 1, wherein the semiconductor device includes a first gate pattern and a second gate pattern on the substrate with a space therebetween and wherein the recess is the space between the first gate pattern and the second gate pattern.

10. The method of claim 1, further comprising:
forming a pad oxide layer pattern and a pad nitride layer pattern on the substrate prior to providing the spin-on-glass solution in the recess; and
planarizing the silicon oxide layer to expose the pad nitride layer pattern after the main thermal treatment is performed.

11. The method of claim 1, further comprising forming a liner on an inner face of the recess, the liner comprising silicon nitride.

12. The method of claim 1, wherein the aspect ratio of the recess exceeds 3.0.

13. A method of manufacturing a silicon oxide isolation layer of a semiconductor device, the method comprising:
forming a trench in a substrate;
forming a liner on an inner face of the trench, the liner comprising silicon nitride.
forming a spin-on-glass film on the substrate and on the liner;
performing a preliminary thermal treatment on the spin-on-glass film at a temperature of about 100° C. to about 300° C.; and
forming the silicon oxide isolation layer by performing a main thermal treatment on the spin-on-glass film at a temperature of about 600° C. to about 1,000° C. and at a pressure of about 1 ATM to about 50 ATM.

14. The method of claim 13, wherein the spin-on-glass film is formed using a spin-on-glass solution that comprises polysilazane.

15. The method of claim 13, wherein the main thermal treatment is performed for about 20 minutes to about 60 minutes.

16. The method of claim 13, wherein the main thermal treatment is performed in an oxidation atmosphere.

17. The method of claim 16, wherein the oxidation atmosphere is produced by using at least one gas selected from the group consisting of a water vapor and an oxygen gas.

18. The method of claim 13, wherein the preliminary thermal treatment is performed at a pressure of about 1 ATM to about 50 ATM in an oxidation atmosphere.

19. The method of claim 13, wherein the aspect ratio of the trench exceeds 3.0.

20. The method of claim 19, wherein the silicon oxide isolation layer is almost free of voids.

21. A method of manufacturing a semiconductor device, the method comprising:
providing a spin-on-glass solution in a recess on a substrate;
forming a spin-on-glass film on the substrate and in the recess;
performing a preliminary thermal treatment on the spin-on-glass film at a temperature of about 100° C. to about 300° C. and at a pressure of about 1 ATM to about 50 atm; and
forming a silicon oxide layer in the recess by performing a main thermal treatment on the spin-on-glass film in the recess at a temperature of about 600° C. to about 1,000° C. and at a pressure of about 1 ATM to about 50 ATM for about 20 minutes to about 60 minutes.

22. The method of claim 21, further comprising forming a liner on an inner face of the recess, the liner comprising silicon nitride.

23. The method of claim 22, further comprising:
forming a pad oxide layer pattern and a pad nitride layer pattern on the substrate prior to forming the liner; and
planarizing the silicon oxide layer to expose the pad nitride layer pattern after the main thermal treatment is performed.

24. The method of claim 23, wherein the silicon oxide layer is almost free of voids.
